(19) United States
(12) Patent Application Publication
(10) Pub. No.: US 2026/0206217 A1
(43) Pub. Date: Jul. 16, 2026

(54) SEMICONDUCTOR STRUCTURES

(71) Applicant: Taiwan Semiconductor Manufacturing Company, Ltd., Hsinchu (TW)

(72) Inventor: Jhon Jhy Liaw, Hsinchu County (TW)

(73) Assignee: Taiwan Semiconductor Manufacturing Company, Ltd., Hsinchu (TW)

(21) Appl. No.: 19/019,353

(22) Filed: Jan. 13, 2025

(51) Int. Cl. H10B 20/20

(52) U.S. Cl. CPC H10B 20/20

(57) ABSTRACT

A semiconductor structure includes a substrate, a transistor, a bit line, a word line, a ground line and a contact. The substrate has a first side and a second side opposite to the first side. The transistor is disposed at the first side of the substrate. The bit line is formed in a first metal layer and disposed on the transistor over the first side of the substrate. The word line is formed in a second metal layer and disposed on the first metal layer over the first side of the substrate. The ground line is formed in a third metal layer and disposed over the second side of the substrate. The contact is disposed over the second side of the substrate and electrically connected to the transistor.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs. However, scaling down has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a front-side layout of a ROM cell array in accordance with some embodiments.

FIG. 1B illustrates a back-side layout of a ROM cell array in accordance with some embodiments.

FIG. 2 and FIG. 3 illustrate cross-sectional views taken along lines I-I and II-II of FIG. 1A and FIG. 1B in accordance with some embodiments.

FIG. 4 illustrates a front-side layout of a ROM cell array in accordance with some embodiments.

FIG. 5A illustrates a front-side layout of a ROM cell array in accordance with other embodiments.

FIG. 5B illustrates a back-side layout of a ROM cell array in accordance with other embodiments.

FIG. 6A illustrates a front-side layout of a ROM cell array in accordance with some embodiments.

FIG. 6B illustrates a back-side layout of a ROM cell array in accordance with some embodiments.

FIG. 7 and FIG. 8 illustrate cross-sectional views taken along lines I-I and II-II of FIG. 6A and FIG. 6B in accordance with some embodiments.

FIG. 9 illustrates a front-side layout of a ROM cell array in accordance with some embodiments.

FIG. 10A illustrates a front-side layout of a ROM cell array in accordance with other embodiments.

FIG. 10B illustrates a back-side layout of a ROM cell array in accordance with other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to a semiconductor structure, and more generally to a read-only-memory (ROM) cell array structure. ROM is a type of solid-state memory which is fabricated with desired data permanently stored in it. Each ROM cell has one transistor either in an “on” state or an “off” state when being selected by a word line and a bit line. Word lines are coupled to the gates of the cell transistors. Bit lines are coupled to the drains of the cell transistors while sources thereof are coupled to a ground line (VSS). Then the “on” or “off” state depends on whether the path of the bit line to the VSS through a particular memory cell is electrically connected or isolated. Such path can be determined by a mask of a coding layer. In some embodiments, when a coding layer is provided to connect the VSS to a cell transistor, the memory cell is in an “on” state; i.e., the logic state of “1”. In some embodiments, when a coding layer is absent between the VSS and a cell transistor, the memory cell is in an “off” state; i.e., the logic state of “0”.

In the convention ROM cell design, the coding layer is usually located on the front-side wiring layer. It means that any design changes (e.g., coding location changes and mask revision) would impact the existing front-side layout. This can reduce a potential wafer loss as well as time to market benefit (coding layer prefers to as close to final step as possible and no impact to performance). However, in the present disclosure, the bit lines and word lines are provided on the front side of a device, while the VSS and the coding layer are moved to the backside of the device. Therefore, a designer has more room for design changes without changing the front-side layout. By such configuration, the cell scaling capability and the front-side bit line/word line RC reduction can be easily achieved.

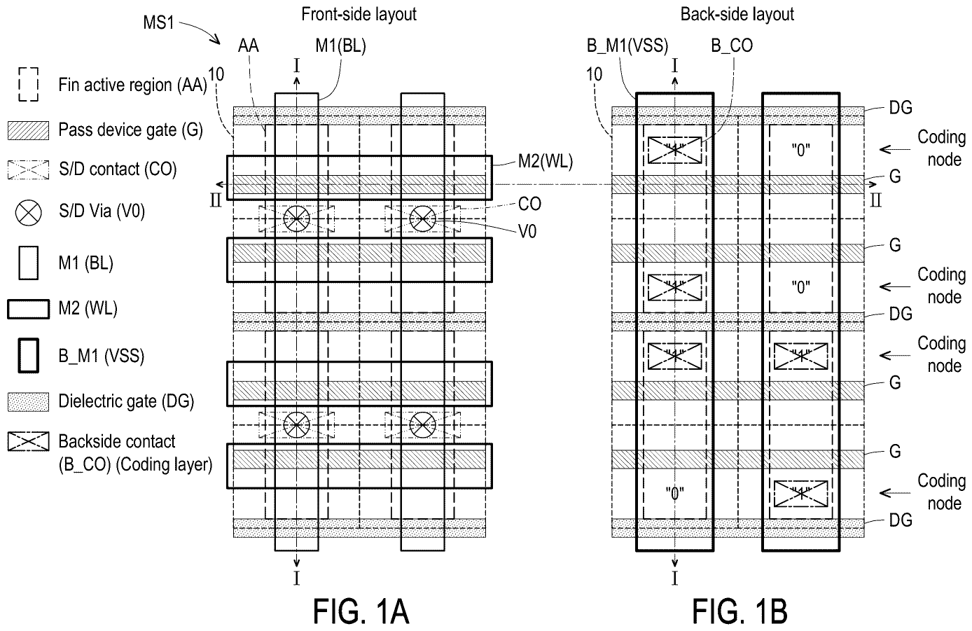

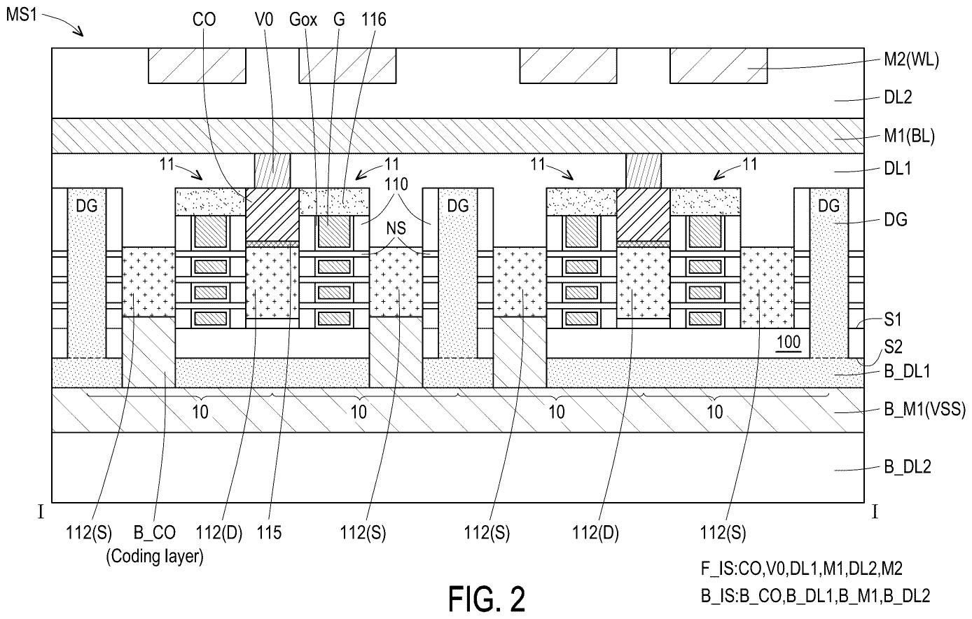

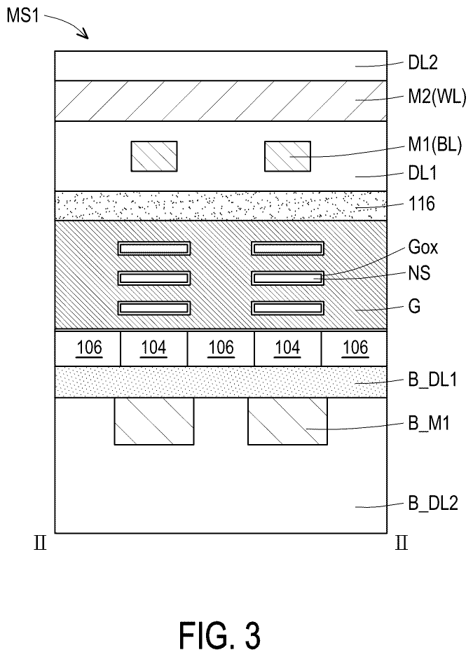

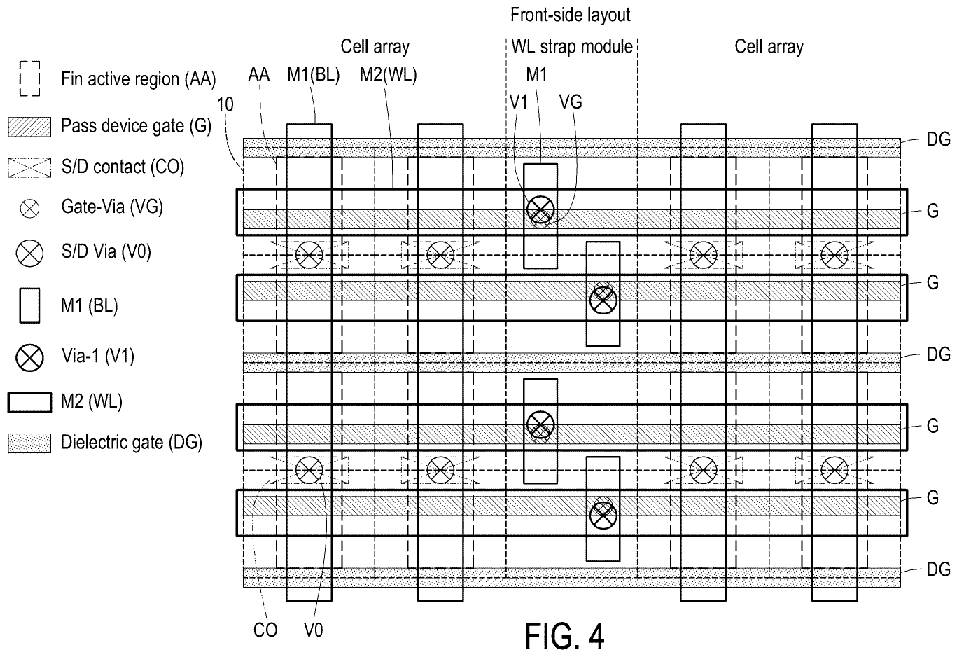

FIG. 1A illustrates a front-side layout of a ROM cell array in accordance with some embodiments. FIG. 1B illustrates a back-side layout of a ROM cell array in accordance with some embodiments. In some embodiments, the layout is stored in a computer or a non-transitory computer-readable medium. FIG. 2 and FIG. 3 are cross-sectional views taken along lines I-I and II-II of FIG. 1A and FIG. 1B in accordance with some embodiments. FIG. 4 illustrates a front-side layout of a ROM cell array in accordance with some embodiments.

Referring to FIG. 1A, FIG. 2 and FIG. 3, a semiconductor structure MS1 (e.g., ROM cell array) includes multiple memory cells 10 (e.g., ROM cells) arranged in an array. Each memory cell 10 includes a substrate 100 and a transistor 11. The substrate 100 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or a combination thereof. The substrate 100 has a first side S1 and a second side S2 opposite to the first sides S1. In some embodiments, the first side S1 is a front side or an active side, while the second side S2 is a backside or a non-active side. In some embodiments, the transistor 11 is disposed at the first side S1 of the substrate 100.

In some embodiments, as shown in the FIG. 1A and FIG. 3, multiple active regions AA defined by isolation structures 106 are arranged discontinuously. In some embodiments, the isolation structures 106 include one or more insulating materials, such as silicon oxide.

In some embodiments, the transistor 11 is a pass transistor having a gate all around (GAA) structure. As shown in FIG. 2 and FIG. 3, each transistor 11 includes nanosheets NS vertically stacked on fins 104 of the substrate 100 and surrounded by a gate electrode G. In some embodiments, for an N-type device, the nanosheets NS include silicon or the like, and the gate electrode G include an N-type work function metal layer and a metal filling layer. The N-type work function metal layer includes one or more of TaN, TaAlC, TiN, TiC, Co, TiAl, HfTi, TiSi and TaSi. The metal filling layer includes Al, W, Cu or the like.

In some embodiments, a gate dielectric layer Gox is formed between each nanosheet NS and the gate electrode G. The gate dielectric layers Gox include a high-k material. Examples of the high-k material include metal oxide, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, the like, or a combination thereof.

In some embodiments, each transistor 11 further includes spacers 110 on sidewalls of the gate electrode G. Each of the spacers 110 may have a single-layer or multi-layer structure. In some embodiments, the spacers 110 include a dielectric material, such as silicon oxide, silicon nitride, SiON, SiC, SiCN, SiCON, or a combination thereof. Other materials such as a low-k material may be applicable. The spacers 110 are referred to as “inner spacers” or “sidewall spacers” in some examples.

In some embodiments, each transistor 11 further includes source/drain regions 112 disposed at two sides of the gate electrode G. The source/drain regions may be referred to as “epitaxial layers”, “strained layers” or “highly doped low resistance materials” in some examples. Source/drain region(s) may refer to a source(S) or a drain (D), individually or collectively dependent upon the context. The source/drain regions 112 are abutted and electrically connected to the nanosheets NS, while the source/drain regions 112 are electrically isolated from the gate electrode G by the inner spacers 110. From another point of view, the nanosheets NS are suspended between the source/drain regions 112. In some embodiments, for an N-type device, the source/drain regions 112 may include silicon, SiC, SiCP, SiP, or the like.

In some embodiments, silicide layers 115 are optionally formed over the source/drain regions 112 respectively. The silicide layers 115 may include tungsten silicide, cobalt silicide, titanium silicide, nickel silicide, the like or a combination thereof.

In some embodiments, cap layers 116 are formed over the gate electrodes G. The cap layers 116 may include dielectric caps. The cap layers 116 include silicon oxide, silicon nitride, SiON, SiC, SiCN, SiCON, metal oxide (e.g., Al₂O₃) or a combination thereof.

In some embodiments, as shown in FIG. 1A and FIG. 2, two transistors 11 are disposed in each active region AA, and one electrical isolation element such as one dielectric gate DG is disposed between two adjacent transistors 11. The dielectric gates DG are defined to isolate the adjacent active regions AA from each other. In some embodiments, the dielectric gates DG penetrate through the nanosheets NS and the substrate 100 and are connected to the underlying backside dielectric layer B_DL1. Each of the dielectric gates DG may have a single-layer or multi-layer structure. In some embodiments, the dielectric gates DG include silicon oxide, silicon nitride, SiON, SiC, SiCN, SiCON, or a combination thereof. The dielectric gates DG are referred to “dummy walls” or “dielectric walls” in some examples.

Referring to FIG. 1A, FIG. 2 and FIG. 3, a front-side interconnect structure F_IS is disposed over the front side S1 of the substrate 100 and electrically connected to the pass transistor 11. In some embodiments, the front-side interconnect structure F_IS includes a dielectric layer (or called front-side first dielectric layer) DL1 disposed over the cap layers 116 and the source/drain regions 112. The dielectric layer DL1 may include silicon oxide, silicon oxynitride, silicon nitride, a low low-k material having a dielectric constant less than 3.5, the like, or a combination thereof. The dielectric layer DL1 is referred to as an “interlayer dielectric (ILD) layer” in some embodiments.

In some embodiments, the front-side interconnect structure F_IS includes metal contacts (or called source/drain contacts) CO landed on and electrically connected to the corresponding source/drain regions 112, and metal vias (or called zeroth vias or source/drain vias) V0 landed on and electrically connected to the metal contacts CO. In some embodiments, the metal contacts CO and metal vias V0 are embedded in the dielectric layer DL1. The metal contacts CO and metal vias V0 include Cu, Al, Ti, Ta, W, Ru, Co, Ni, the like, or a combination thereof. In some embodiments, a metal liner layer may be disposed between each metal contact CO and the dielectric layer DL1 and between each metal via V0 and the dielectric layer DL1. In some embodiments, the metal liner layer includes a seed layer and/or a barrier layer. The seed layer may include Ti/Cu. The barrier layer may include Ta, TaN, Ti, TiN, CoW or a combination thereof.

In some embodiments, the front-side interconnect structure F_IS includes metal layers (or called front-side first metal layers) M1 disposed over the dielectric layer DL1 and electrically connected to multiple pass transistors 11. In some embodiments, the bit lines BL are formed in the metal layers M1 and electrically connected to source/drain regions 112 of the multiple pass transistors 11 through the metal vias V0 and the metal contacts CO. From a top view, multiple metal layers M1 are formed in parallel with each other, continuously across multiple active regions AA and extend along a first direction (e.g., Y-direction), as shown in FIG. 1A.

In some embodiments, the front-side interconnect structure F_IS includes metal layers (or called front-side second metal layers) M2 and underlying vias (not shown in this cross-section) embedded in a dielectric layer (or called front-side second dielectric layer) DL2. In some embodiments, the word lines WL are formed in the metal layers M2 and electrically connected to the gate electrodes G of the pass transistors 11 through multiple WL strap modules (as shown in FIG. 4). Each WL strap module includes, from bottom to top, a gate via VG, a metal layer M1 and a first via V1. From a top view, multiple metal layers M2 are formed in parallel with each other, continuously across multiple active regions AA and extend along a second direction (e.g., X-direction) different from the first direction, as shown in FIG. 1A. The metal layers M1 and M2 include Cu, Al, Ti, Ta, W, Ru, Co, Ni, the like, or a combination thereof. In some embodiments, a metal liner layer may be disposed between the dielectric layer DL2 and each of the metal layers M1 and M2. In some embodiments, the metal liner layer includes a seed layer and/or a barrier layer. The seed layer may include Ti/Cu. The barrier layer may include Ta, TaN, Ti, TiN, CoW or a combination thereof. The dielectric layer DL2 may include silicon oxide, silicon oxynitride, silicon nitride, a low low-k material having a dielectric constant less than 3.5, the like, or a combination thereof. The dielectric layer DL2 is referred to as an “inter-metal dielectric (IMD) layer” in some embodiments.

Now referring to FIG. 1B, FIG. 2 and FIG. 3, a back-side interconnect structure B_IS is disposed over the back side S2 of the substrate 100 and electrically connected to the pass transistor 11.

In some embodiments, the back-side interconnect structure B_IS includes a dielectric layer (or called backside first dielectric layer) B_DL1 disposed over the back side S2 of the substrate 100 and in contact of the dielectric gates DG. The dielectric layer B_DL1 may include silicon oxide, silicon oxynitride, silicon nitride, a low low-k material having a dielectric constant less than 3.5, the like, or a combination thereof.

In some embodiments, the back-side interconnect structure B_IS includes metal contacts (or called backside contacts) B_CO electrically connected to the selected source/drain regions 112. In some embodiments, the metal contacts B_CO penetrate through the dielectric layer B_DL1 and the substrate 100 and landed on the selected source/drain regions 112. The locations of the metal contacts B_CO are defined by the mask of a coding layer, so the metal contacts B_CO are referred as a “coding layer” or “coding switch” or “coding contact” in some examples. The metal contacts B_CO include Cu, Al, Ti, Ta, W, Ru, Co, Ni, the like, or a combination thereof. In some embodiments, a metal liner layer may be disposed between each metal contact B_CO and the dielectric layer B_DL1. In some embodiments, the metal liner layer includes a seed layer and/or a barrier layer. The seed layer may include Ti/Cu. The barrier layer may include Ta, TaN, Ti, TiN, CoW or a combination thereof.

In some embodiments, the back-side interconnect structure B_IS includes metal layers B_M1 (or called backside first metal layer) over the dielectric layer B_DL1 and in contact with the metal contacts B_CO. In some embodiments, the VSS lines are formed in the metal layers B_M1 and electrically connected to the metal contacts B_CO. From a top view, multiple metal layers B_M1 are formed in parallel with each other, continuously across multiple active regions AA and extend along the first direction (e.g., Y-direction), as shown in FIG. 1B. The metal layers B_M1 include Cu, Al, Ti, Ta, W, Ru, Co, Ni, the like, or a combination thereof. In some embodiments, a metal liner layer may be disposed between the adjacent dielectric layer B_DL2 and each of the metal layers B_M1. In some embodiments, the metal liner layer includes a seed layer and/or a barrier layer. The seed layer may include Ti/Cu. The barrier layer may include Ta, TaN, Ti, TiN, CoW or a combination thereof. The dielectric layer (or called backside second dielectric layer) B_DL2 may include silicon oxide, silicon oxynitride, silicon nitride, a low low-k material having a dielectric constant less than 3.5, the like, or a combination thereof.

In the above embodiments, the front-side interconnect structure F_IS includes two levels of metal materials, and the back-side interconnect structure B_IS includes one level of metal materials. However, the number of levels of metal materials of the front-side interconnect structure F_IS or the back-side interconnect structure B_IS is not limited by the present disclosure. For example, the front-side interconnect structure F_IS may include six levels or more levels of metal materials, and the back-side interconnect structure B_IS may include three levels or more levels of metal materials.

Besides, under-bump metallization (UBM) pads (e.g., I/O pads and power pads) may be disposed over and electrically connected to the back-side interconnect structure B_IS on the second side S2 of the substrate 100, and bumps may be disposed on the UBM pads. The UBM pads may include Cu, Ni or a combination thereof. The bumps may be solder bumps, lead-free bumps and/or may include metal pillars (e.g., copper pillars), solder caps formed on metal pillars, and/or the like.

In some embodiments, along the cross-sectional line I-I, four logic states of “1”, “1”, “1” and “0” are stored in four pass transistors 11 of the semiconductor structure MS1, as shown in FIG. 1B. Specifically, as shown in FIG. 2, the left-most memory cell 10 includes a pass transistor 11 and a coding layer B_CO. The pass transistor 11 is an N-type transistor. A drain terminal 112(D) of the pass transistor 11 is electrically connected to a bit line BL through a metal contact CO and a metal via V0. A gate terminal of the pass transistor 11 is electrically connected to a word line WL through a WL strap module (shown in FIG. 4). A source terminal 112(S) of the pass transistor 11 is electrically connected to the coding layer B_CO. The coding layer B_CO is disposed between the pass transistor 11 and a VSS line, so the pass transistor 11 of the left-most memory cell 10 is in an “on” state; i.e., the logic state of “1”. Each of the middle two memory cells 10 has a structure similar to that of the left-most memory cell 10, so each of the pass transistors 11 of the middle two memory cells 10 is in an “on” state; i.e., the logic state of “1”.

Besides, as shown in FIG. 2, the right-most memory cell 10 includes a pass transistor 11. The pass transistor 11 is an N-type transistor. The drain terminal 112(D) of the pass transistor 11 is electrically connected to a bit line BL through a metal contact CO and a metal via V0. The gate terminal of the pass transistor 11 is electrically connected to a word line WL through a WL strap module (shown in FIG. 4). The source terminal 112(S) of the pass transistor 11 is not electrically coupled to a coding layer B_CO. The coding layer B_CO is absent between the pass transistor 11 and a VSS line, so the pass transistor 11 of the right-most memory cell 10 is in an “off” state; i.e., the logic state of “0”.

The embodiments of FIG. 1A to FIG. 4 illustrate a specific ROM cell array with desired data permanently stored in it, but the present disclosure is not limited thereto. Thousands of ROM cell array structures can be provided by adjusting the respective ROM cell either in an “on” state or an “off” state when being selected by a word line, a bit line, and the optional coding layer upon the design requirements.

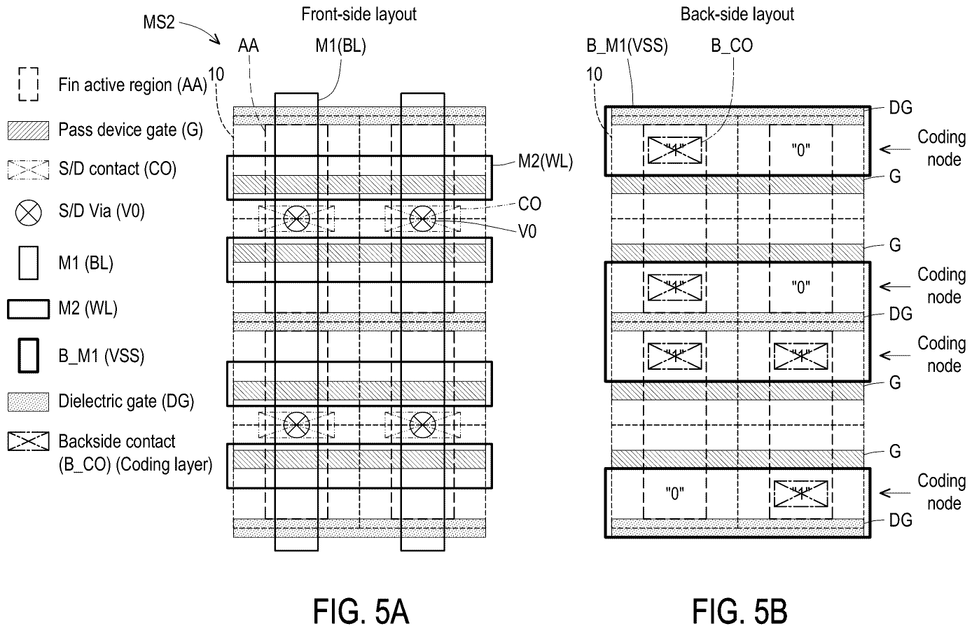

The above embodiments of FIG. 1A and FIG. 1B in which the backside metal layers B_M1 (VSS lines) extend in a direction in parallel with the direction of the metal lines M1 (bit lines) are provided for illustration purposes, and are not construed as limiting the present disclosure. In other embodiments, the backside metal layers B_M1 (VSS lines) extend in a direction perpendicular to the direction of the metal lines M1 (bit lines), as shown in the semiconductor structure MS2 of FIG. 5A and FIG. 5B.

In the above embodiments, each memory cell 10 includes one pass device and one dielectric gate DG. The drain node of the pass device is electrically connected to a bit line, the gate node of the pass transistor 11 is electrically connected to a word line, the source node of the pass device is electrically connected to a coding layer. The dielectric gate DG breaks the active regions AA with a dummy dielectric gate structure for coding node to adjacent memory cells. The dielectric gate DG has a trench depth that is deeper than the device's bottom channel region by a distance of about 10 nm to 150 nm.

As discussed above, one electrical isolation element such as a dielectric gate DG is disposed between and electrically insulated from two adjacent transistors 11. As shown in FIG. 2, the dielectric gate DG and the adjacent the adjacent pass transistors 11 have different materials and structures.

The dielectric gate DG is provided for illustration purposes. However, the preset disclosure is not limited thereto. In other embodiments, the electrical isolation element and the adjacent the adjacent pass transistors may have similar material and structure, so as to simplify the process steps.

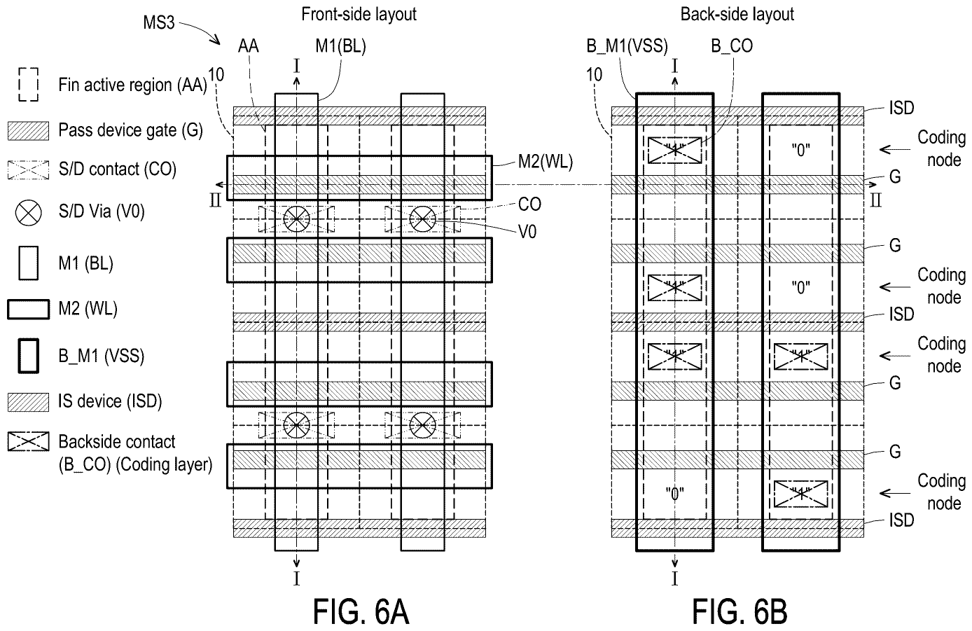

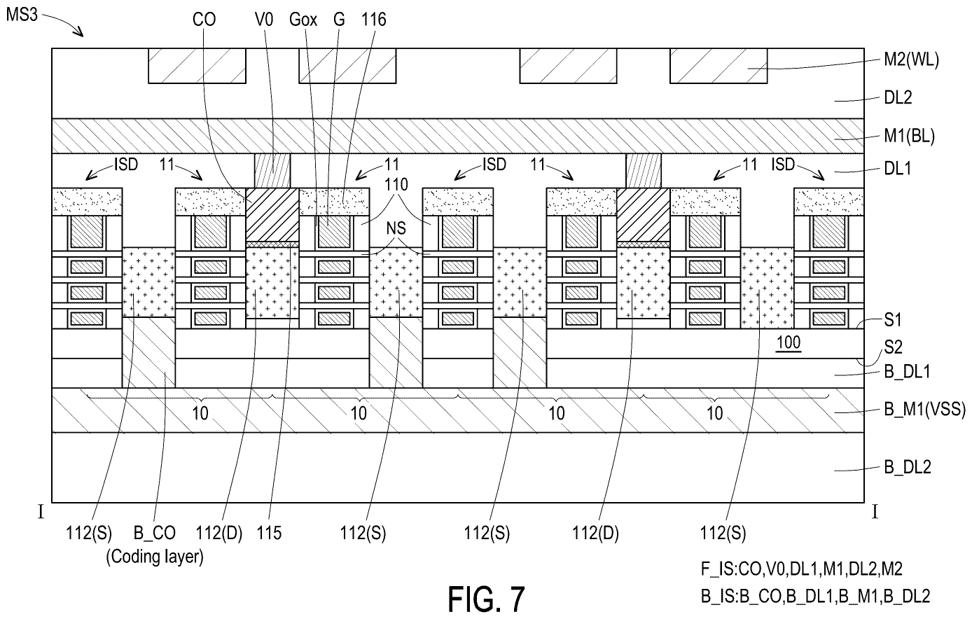

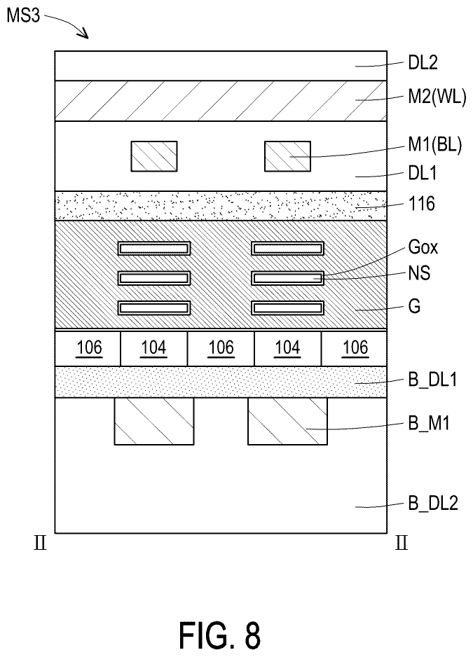

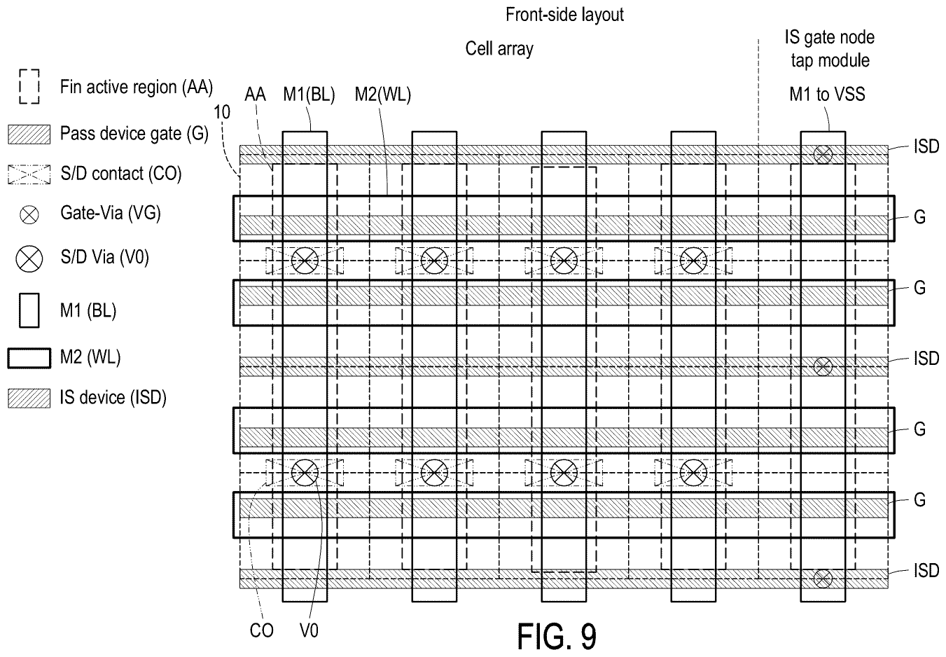

FIG. 6A illustrates a front-side layout of a ROM cell array in accordance with some embodiments. FIG. 6B illustrates a back-side layout of a ROM cell array in accordance with some embodiments. In some embodiments, the layout is stored in a computer or a non-transitory computer-readable medium. FIG. 7 and FIG. 8 illustrate cross-sectional views taken along lines I-I and II-II of FIG. 6A and FIG. 6B in accordance with some embodiments. FIG. 9 illustrates a front-side layout of a ROM cell array in accordance with some embodiments. The materials and configurations of elements of the semiconductor structure MS3 in FIG. 6A to FIG. 9 are similar to those of elements of the semiconductor structure MS1 in FIG. 1A to FIG. 4, so the difference between them is described below, and the similarity is not iterated herein.

In FIG. 6A, along the cross-sectional line I-I, four memory cells 10 are arranged in the elongated continuous active region AA, and one isolation device ISD is disposed between and electrically insulated from two adjacent transistors 11. As shown in FIG. 7, the isolation device ISD and the adjacent the adjacent pass transistors 11 have similar structures. The isolation device ISD can be turned off and effectively perform the isolation function. In some embodiments, two source/drain regions 112 of each isolation device ISD are electrically connected to the VSS line through two backside metal contacts B_CO, and the gate of the isolation device ISD is connected to the VSS line through an IS gate node tap module (as shown in FIG. 9). Each IS gate node tap module is electrically connected to a metal layer M1 through a gate via VG, and the metal layer M1 is further electrically connected to the VSS line through a connection structure (e.g., a deep through via or multiple stacked vias). In some embodiments, another VSS line formed in a front-side metal layer is disposed on the front side S1 of the substrate 100, and the IS gate node tap module is electrically connected to another VSS line on the front side S1 of the substrate 100.

Therefore, the isolation device ISD is permanently in an off state, and does not perform any electronic function in the ROM cell array. The presence of the isolation device ISD provides layout benefits.

Although the VSS has been described to turn off the isolation device ISD of FIG. 6A to FIG. 9, a skilled artisan would realize that any other voltage that is lower than the threshold voltage of the isolation device ISD, the isolation device ISD can be turned off and effectively perform the isolation function. Such design would not significantly affect the size of the ROM cell array.

Two adjacent memory cells 10 shares one isolation device ISD, and the isolation device ISD includes source/drain nodes and a gate terminal. The gate terminal of the isolation device ISD is electrically connected to VSS, one of source/drain nodes is located within one adjacent memory cell and electrically connected to VSS, and another source/drain node is located within another adjacent memory cell and electrically connected to VSS.

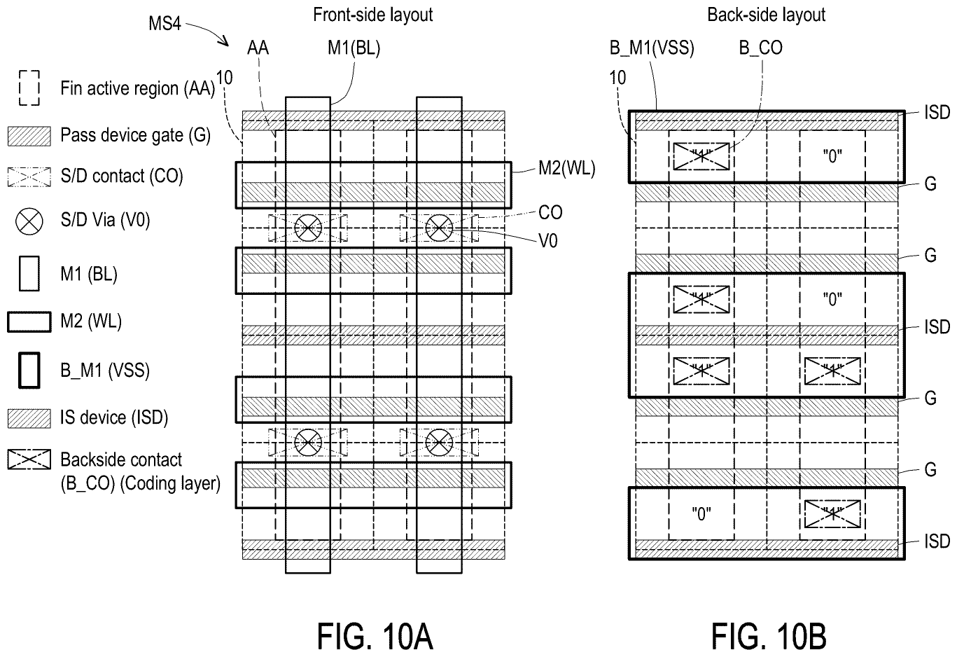

The above embodiments of FIG. 6A and FIG. 6B in which the backside metal layers B_M1 (VSS lines) extend in a direction in parallel with the direction of the metal lines M1 (bit lines) are provided for illustration purposes, and are not construed as limiting the present disclosure. In other embodiments, the backside metal layers B_M1 (VSS lines) extend in a direction perpendicular to the direction of the metal lines M1 (bit lines), as shown in the semiconductor structure MS4 of FIG. 10A and FIG. 10B.

The semiconductor structures of the present disclosure are illustrated below. In some embodiments, a semiconductor structure MS1/MS2/MS3/MS4 includes a substrate 100, a transistor 11, a bit line a word line, a VSS line and a coding layer. The substrate 100 has a first side S1 and a second side S2 opposite to the first side S1. The transistor 11 is disposed at the first side S1 of the substrate 100. The bit line is formed in a first metal layer M1 and disposed on the transistor 11 over the first side S1 of the substrate 100. The word line is formed in a second metal layer M2 and disposed on the first metal layer M1 over the first side S1 of the substrate 100. The VSS line is formed in a third metal layer B_M1 and disposed over the second side S2 of the substrate 100. The coding layer is disposed over the second side S2 of the substrate 100 and electrically connected to the transistor 11.

In some embodiments, the first side S1 is an active side, and the second side S2 is a non-active side. In some embodiments, the first side S1 is a front side, and the second side S2 is a backside. In some embodiments, the coding layer is formed in a contact layer B_CO and in a plug form, and disposed between the third metal layer B_M1 and the transistor 11.

In some embodiments, from a top view, the VSS line is in parallel with the bit line. In some embodiments, from a top view, the VSS line is in parallel with the word line.

In some embodiments, the transistor 11 is a pass transistor of a read only memory (ROM) cell. In some embodiments, the transistor 11 has a GAA structure. However, the present disclosure is not limited thereto. In other embodiments, the transistor 11 has a FinFET structure.

In some embodiments, the coding layer is electrically connected to a source S of the transistor 11. In some embodiments, the bit line is electrically connected to a drain D of the transistor.

In some embodiments, the semiconductor structure MS1/MS2/MS3/MS4 further includes bump pads and bumps located on the second side S2 of the substrate 100 and electrically connected to the third metal layer B_M1.

In some embodiments, the semiconductor structure MS3/MS4 has first transistor and a second transistor disposed in an elongated continuous active region AA, and further has an isolation device ISD disposed in the elongated continuous active region AA and disposed between the first transistor and the second transistor. The isolation device ISD has substantially the same structure as gates of the first and second transistors, and is coupled to a predetermined voltage to shut off any active current across a section of the elongated continuous active region beneath the isolation device ISD, so as to electrically isolate the first transistor from the second transistor. In some embodiments, the first and second transistors are NMOS transistors and the predetermined voltage is a ground (VSS).

In some embodiments, the first source of the first transistor is connected to the predetermined voltage (VSS) by one metal contact B_CO, and there is no contact for the second source of the second transistor. Specifically, the second source of the second transistor is not connected to the predetermined voltage (VSS). From another point of view, the coding switch is “on” (e.g., the metal contact B_CO is “present”) for the first transistor, while the coding switch is “off” (e.g., the metal contact B_CO is “absent”) for the second transistor.

In some embodiments, a semiconductor structure MS1/MS2/MS3/MS4 includes a substrate 100, a transistor 11, a bit line, a word line, a VSS line and a coding layer. The substrate 100 has a front side S1 and a backside S2 opposite to the front side S1. The transistor 11 is disposed over the front side S1 of the substrate 100. The bit line and a word line are formed in a front-side interconnect structure F_IS over the front side S1 of the substrate 100. The VSS line and the coding layer are formed in a backside interconnect structure B_IS and disposed over the back side S2 of the substrate 100.

In some embodiments, the coding layer penetrates through the substrate 100 and is electrically connected to the transistor 11. In some embodiments, the coding layer is formed in a contact layer B_CO of the backside interconnect structure B_IS and in physical contact with a source S of the transistor 11. In some embodiments, the coding layer is disposed between the VSS line and the transistor 11.

In some embodiments, the bit line is formed in a first metal layer M1 of the front-side interconnect structure F_IS and electrically connected to a drain D of the transistor 11. In some embodiments, the word line is formed in a second metal layer M2 of the front-side interconnect structure F_IS and electrically connected to a gate G of the transistor 11.

In some embodiments, the semiconductor structure MS1/MS2/MS3/MS4 further includes an electrical isolation element DG/ISD disposed adjacent to the transistor 11. In some embodiments, the electrical isolation element is formed as a dielectric gate DG, and the dielectric gate DG and the adjacent transistor 11 have different structures. In some embodiments, the electrical isolation element is formed as an isolation device ISD, and the isolation device ISD and the adjacent transistor 11 has the same structure.

In some embodiments, a semiconductor structure MS1/MS2/MS3/MS4 includes a pass transistor 11 and an electrical isolation element DG/ISD. The pass transistor 11 includes a drain D, a gate G and a source S. The drain D is electrically coupled to a bit line, wherein the bit line is formed in a first metal layer M1 over the front side of the substrate. The gate G is electrically coupled to a word line, wherein the word line is formed in a second metal layer M2 over the first metal layer M1. The source S is electrically coupled to a coding layer, wherein the coding layer is formed in a contact layer DG/ISD that penetrates through the substrate 100. The electrical isolation element DG/ISD is disposed on the backside of the substrate 100 adjacent to the pass transistor 11.

In some embodiments, the semiconductor structure MS1/MS2/MS3/MS4 further includes a VSS line formed in a third metal layer B_M1, wherein the VSS line and the coding layer are disposed at the same side. In some embodiments, two source/drain regions 112 of the electrical isolation element are electrically coupled to the VSS line. In some embodiments, the gate G of the electrical isolation element is electrically coupled to the VSS line.

In some embodiments, the electrical isolation element is a dielectric gate DG, and the isolation transistor ISD and the adjacent pass transistor 11 have different structures. In some embodiments, the electrical isolation element is an isolation transistor ISD, and the isolation transistor ISD and the adjacent pass transistor 11 have the same structure.

In some embodiments, the semiconductor structure MS1/MS2 further includes a WL strap module located between two ROM cells and made an electrically connection between the word line and the gate node of pass transistor.

In view of the above, in the present disclosure, the bit lines and word lines are provided on the front side of a device, while the VSS and the coding layer are moved to the backside of the device. By such configuration, the cell scaling capability and the front-side bit line/word line RC reduction can be easily achieved.

The front-side is fully uniform layout no matter coding “1” or “0” and therefore benefited to manufacturing margin. Specifically, in the front-side, the semiconductor structure of the present disclosure provides the same metal routing layer and RC performance for bit lines and word lines without being impacted by coding (“1” & “0”) layer revising.

The semiconductor structure of the present disclosure allows a designer to use either a backside contact code (in contact with S/D junction area) and/or a backside via code (between the backside contact and a backside metal layer), without changing the front-side layout.

According to some embodiments, a semiconductor structure includes a substrate, a transistor, a bit line, a word line, a VSS line (or ground line) and a contact. The substrate has a first side and a second side opposite to the first side. The transistor is disposed at the first side of the substrate. The bit line is formed in a first metal layer and disposed on the transistor over the first side of the substrate. The word line is formed in a second metal layer and disposed on the first metal layer over the first side of the substrate. The VSS line is formed in a third metal layer and disposed over the second side of the substrate. The contact is disposed over the second side of the substrate and electrically connected to a source/drain feature of the transistor, wherein an electrical conductivity of the contact is greater than an electrical conductivity of the source/drain feature.

According to Some Embodiments, a Semiconductor Structure Includes a Substrate, a transistor, a bit line, a word line, a VSS line and a contact. The substrate has a front side and a backside opposite to the front side. The transistor is disposed over the front side of the substrate. The bit line and a word line are formed in a front-side interconnect structure over the front side of the substrate. The VSS line and the contact are formed in a backside interconnect structure and disposed over the back side of the substrate, wherein a contact extends through a backside dielectric layer and is electrically connected to the transistor.

According to some embodiments, a semiconductor structure includes a pass transistor and an electrical isolation element. The pass transistor includes a drain, a gate and a source. The drain is electrically coupled to a bit line, wherein the bit line is formed in a first metal layer over a substrate. The gate is electrically coupled to a word line, wherein the word line is formed in a second metal layer over the first metal layer. The source is electrically coupled to a contact, wherein the contact is formed in a plug form penetrating through a backside dielectric layer and the substrate. The electrical isolation element is disposed on the substrate adjacent to the pass transistor.

The above illustration provides many different embodiments or embodiments for implementing different features of the invention. Specific embodiments of components and processes are described to help clarify the invention. These are, of course, merely embodiments and are not intended to limit the invention from that described in the claims.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate having a first side and a second side opposite to the first side;
a transistor disposed at the first side of the substrate;
a bit line formed in a first metal layer and disposed on the transistor over the first side of the substrate;
a word line formed in a second metal layer and disposed on the first metal layer over the first side of the substrate;
a ground line formed in a third metal layer and disposed over the second side of the substrate; and
a contact disposed over the second side of the substrate and electrically connected to a source/drain region of the transistor, wherein an electrical conductivity of the contact is greater than an electrical conductivity of the source/drain region.

2. The semiconductor structure of claim 1, wherein the first side is an active side, and the second side is a non-active side.

3. The semiconductor structure of claim 1, wherein the contact is formed in a plug form and disposed between the third metal layer and the transistor.

4. The semiconductor structure of claim 1, wherein from a top view, the ground line is in parallel with the bit line.

5. The semiconductor structure of claim 1, wherein from a top view, the ground line is in parallel with the word line.

6. The semiconductor structure of claim 1, wherein the transistor is a pass transistor of a read only memory (ROM) cell, and the contact is a coding contact.

7. The semiconductor structure of claim 1, wherein the source/drain region is a source of the transistor, and the contact is landed on the source of the transistor.

8. The semiconductor structure of claim 1, wherein the bit line is electrically connected to a drain of the transistor.

9. A semiconductor structure, comprising:
a substrate having a front side and a backside opposite to the front side;
a transistor disposed over the front side of the substrate;
a bit line and a word line formed in a front-side interconnect structure over the front side of the substrate; and
a ground line and a contact formed in a backside interconnect structure and disposed over the back side of the substrate,
wherein a contact extends through a backside dielectric layer and is electrically connected to the transistor.

10. The semiconductor structure of claim 9, wherein the contact further penetrates through the substrate and is electrically connected to the transistor.

11. The semiconductor structure of claim 9, wherein the contact is formed in a plug form of the backside interconnect structure and in physical contact with a source of the transistor.

12. The semiconductor structure of claim 9, wherein the contact is disposed between the ground line and the transistor.

13. The semiconductor structure of claim 9, wherein the bit line is formed in a first metal layer of the front-side interconnect structure and electrically connected to a drain of the transistor.

14. The semiconductor structure of claim 9, wherein the word line is formed in a second metal layer of the front-side interconnect structure and electrically connected to a gate of the transistor.

15. The semiconductor structure of claim 9, further comprising an electrical isolation element disposed adjacent to the transistor.

16. A semiconductor structure, comprising:
a transistor comprising:
a drain electrically coupled to a bit line, wherein the bit line is formed in a first metal layer over a substrate;
a gate electrically coupled to a word line, wherein the word line is formed in a second metal layer over the first metal layer; and
a source electrically coupled to a contact, wherein the contact is formed in a plug form penetrating through a backside dielectric layer and the substrate; and
an electrical isolation element disposed on the substrate adjacent to the transistor.

17. The semiconductor structure of claim 16, further comprising a ground line formed in a third metal layer, wherein the ground line and the contact are disposed at the same side.

18. The semiconductor structure of claim 17, wherein two source/drain regions of the electrical isolation element is electrically coupled to the ground line.

19. The semiconductor structure of claim 16, wherein the electrical isolation element is a dielectric gate, and the dielectric gate and the transistor have different structures.

20. The semiconductor structure of claim 16, wherein the electrical isolation element is an isolation transistor, and the isolation transistor and the transistor have the same structure.
